(19) United States
(12) Patent Application Publication
(10) Pub. No.: US 2003/0226070 A1
(43) Pub. Date: Dec. 4, 2003

(54) Clock extraction circuit

(75) Inventors: Tetsuhiro Fukao, Tokyo (JP); Harufusa Kondou, Tokyo (JP); Masahiko Ishiwaki, Tokyo (JP); Shigeki Kohama, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: MITSUBISHI DENKI KABUSHIKI KAISHA, Tokyo (JP)

(21) Appl. No.: 10/294,682

(22) Filed: Nov. 15, 2002

(30) Foreign Application Priority Data
Jun. 3, 2002 (JP) 2002-161913

(51) Int. Cl. G11B 5/00; G06K 5/04; G11B 20/20; G01R 31/28

(52) U.S. Cl. 714/700

(57) ABSTRACT

A clock extraction circuit includes an edge detection unit for detecting a phase at which a trailing edge or a leading edge of input data is coincided with each other, and a phase judgement unit for comparing an edge position of the detected input data and a position of an input clock and for putting a weight, wherein the weight is put so that a shifting amount of the input clock is varied depending on a difference between the edge position of the input data and the position of the input clock.

### BACKGROUND OF THE INVENTION

1. Field of the Invention

This invention relates to a clock extraction circuit for data transmission, especially to a clock extraction circuit which is able to extract a clock from input data, even when random jitter or frequency shit or the like have been occurred.

2. Description of the Related Art

Generally, in data transmission a main cause for jitters that bring about an erroneous selection of data is attributable to deterministic jitter and random jitter. The deterministic jitter is peculiar to a transmission line and resulted from frequency bandwidth of the transmission line and impedance unmatching. On the other hand, the random jitter is randomly generated irrespective of the transmission line and resulted from power noises or thermal fluctuations. As data transfers at high speed it has a tendency to increase a ratio dominated for the most part by random noises over jitters.

FIG. 8 is a schematic diagram explaining an existence probability of edges when data is affected by the random jitter.

The random jitter generally has a Gaussian distribution as shown in FIG. 8. In FIG. 8, the vertical axis designates the existence probability of edges and the horizontal axis designates time, respectively. As shown in FIG. 7, with the position where no jitters can be found as the center, the smaller jitters become the larger the existence probability of an edge that the jitter may have becomes. Conversely, the larger the jitters become the smaller the existence probability of the edge that the jitter may have becomes. Further, with jitter=0 as the center, the random jitter has a property that it is symmetric at both plus (+) and minus (−) sides.

Here, the region from +n to −n is defined as a dead region. The random jitter generally has a Gaussian distribution as mentioned above but, when the random jitter has occurred, the provision of this dead region in the center of the Gaussian distribution endures an influence of the random jitter. That is, time constant increases relative to the random jitter. Meanwhile, when the frequency shift has occurred, the dead region is not affected by it for the reason that data is input to a clock data recovery (CDR) circuit, with the center of the Gaussian distribution being shifted.

FIG. 9 a block diagram schematically showing a cause that brings about the frequency shift.

What has to be considered in data transmission is the frequency shift occurred between the transmission and the reception sides. In the case of data transmission, in general, clocks for transmission and reception are generated on the basis of a common clock source 90 shared between a transmission side LSI 100 and a reception side LSI 110. In this event, however, a delay time taken from the clock source 90 to the transmission side LSI 100 and that from the clock source 90 to the reception side LSI 110 are not necessarily equal. When frequency fluctuations have occurred in the clock source 90, a frequency difference is, from microscopic point of view, made between the transmission side LSI 100 and the reception side LIS 110.

FIG. 10 is a block diagram showing a configuration of the conventional clock extraction circuit disclosed, e.g., in Publication of Unexamined Patent Application No. 7-162402.

Referring to FIG. 10, reference numeral 120 denotes a data input terminal, 130 denotes a clock input terminal, 140 denotes a delay unit including therein a plurality of delay lines (not shown), 150 denotes a phase judgement unit for judging a phase by comparing an edge of input data and a leading edge of a clock, 160 denotes a counter for determining a unit of selection, as well as for leading or delaying a phase of data, 170 denotes a data selector for outputting data and data of a proper phase margin based on results from the phase judgement unit 150, 180 denotes a data output terminal. In the conventional clock extraction circuit that is essential for data transmission, when the currently selected clock and an edge position of the input data are closed each other, the configuration is generally taken where the phase margin is secured by keeping away from each other.

The operation of the conventional clock extraction circuit will now be described.

When data is input from the data input terminal 120 to the delay unit 140, the input data goes through different delay elements, so that a plurality of data delayed in various ways are outputted from outputs DO to Dn. The phase judgement unit 150 inputs all of the data to check if a change point of data and the leading edge of a clock are closed each other, or the duty of a sampling timing of a clock is dulled. If so, a clock (UP) for leading a phase of data or a clock (DOWN) for delaying a phase of data is inputted depending on how things stand now. Then, the phase judgement unit 150 supplies a count signal for determining the unit of selection to the counter 160. The data selector 170 selects and outputs data of a proper phase margin between the data and clock based on results from the phase judgement unit 150. In this manner, the conventional phase judgement unit 150 has been taken a way of judging a phase difference for all of the data and outputting a signal for leading or delaying a phase of data at respective positions.

Therefore, the conventional clock extraction circuit thus configured as mentioned above inevitably involves problems as follows.

FIG. 11 is a conventional schematic diagram explaining a response and weighting when data is affected by the random jitter.

In the case where the counter 160 is configured such that the data selector 170 is immediately affected by an output from the phase judgement unit 150, it has a possibility that wrong data might be selected due to a trifling difference in a random number when data is affected by the random jitter. FIG. 11 shows a data input with eye patterns. In FIG. 11, when an edge exists at the position f versus the edge existence probability distribution, since the phase judgement unit 150 judges that a clock position and an edge position are closed each other, the unit 150 tries to shift the clock position backward. However, because the ideal data latch position e is not shifted, it follows that the data latch position of the clock extraction circuit shifts by a gap g relative to the ideal data latch position e. As a result, a bit error would probably be taken place. It is to be noted that this corresponds to situations where the counter 160 has a small count threshold and time constant.

FIG. 12 is a conventional schematic diagram explaining a response and weighting when data is affected by the frequency shift.

Then, in the case where the counter 160 is configured such that the data selection unit 170 is gradually influenced by an output from the phase judgement unit 150, when data is affected by the frequency shift, the time that requires for the response to reflect on a data selection becomes longer. As a result, it would probably be misselection of data. Here, when the frequency shift has occurred, the ideal data latch position h will be shifted backward. The phase judgement unit 150 can detect this shift, but a more time is required in order that the results exert an influence upon the data selector 160, as the counter 160 has a large count threshold. The data latch position of the clock extraction circuit shifts by a gap i relative to the ideal data latch position h. As a result, a bit error would probably be taken place. It is to be noted that this corresponds to situations where the counter 160 has a large count threshold and time constant.

In the conventional clock extraction circuit, even if the count and time constant are small or large, when data is affected by the random jitter and the frequency shift, a bit error is likely to be taken place.

### SUMMARY OF THE INVENTION

The present invention has been made to solve the above problems, and an object thereof is to provide a clock extraction circuit which is able to manage random jitter and frequency shift.

A clock extraction circuit according to the present invention includes an edge detection unit for detecting a phase at which a trailing edge or a leading edge of the input data is coincided with each other; a phase judgement unit for comparing an edge position of the detected input data and a position of input clock, and for putting a weight; wherein the weight is put so that a shifting amount of the clock is changed in accordance with a difference between the edge position of the input data and the position of the input clock.

As described above, according to the present invention, since the contents of the weighting table are set such that a small weight is put on the random jitter having a Gaussian distribution, while a large weight is put on the frequency shift, it can manage both random jitter and the frequency shift.

A clock extraction circuit according to the present invention includes an edge detection unit for detecting a phase at which a trailing edge or a leading edge of the input data is coincided with each other; a phase judgement unit for comparing an edge position of the detected input data and a position of an input clock, and for putting a weight; wherein the weight is varied depending on whether or not a difference between an edge position of the input data and the position of the input clock falls within a predetermined region.

As described above, according to the present invention, since the contents of the weighting table is set such that a weight of “0” is put on the random jitter having a Gaussian distribution, while a weight of “1” is put on the frequency shift, it can not only manage both the random jitter and the frequency shift but reduce circuit scale and power consumption. In addition, the invention realizes high speed and high quality data transmission.

The above and other objects and the attendant advantages of the invention will become readily apparent by referring to the following detailed description of the preferred embodiments when considered in conjunction with the accompanying drawings.

### BRIEF DESCRIPTION OF THE DRAWINGS

FIG. 1 is a block diagram showing an exemplary configuration of a clock extraction circuit of a first embodiment.

FIG. 2 is a block diagram showing an exemplary internal configuration of the phase judgement unit shown in FIG. 1 of the first embodiment.

FIG. 3 is a table showing exemplary contents of the weighting table.

FIG. 4 is a schematic diagram explaining a response and weighting when data is affected by the random jitter.

FIG. 5 is a schematic diagram explaining a response and weighting when data is affected by the frequency shift.

FIG. 6 is schematic diagram explaining a response and weighting when data is affected by the random jitter of the second embodiment.

FIG. 7 is a schematic diagram explaining a response and weighting when data is affected by the frequency shift.

FIG. 8 is a schematic diagram explaining an existence probability of an edge when data is affected by the random jitter.

FIG. 9 is a block diagram schematically showing a cause that brings about the frequency shift.

FIG. 10 is a block diagram showing a configuration of the conventional clock extraction circuit.

FIG. 11 is a schematic diagram explaining a response when data is affected by the random jitter.

FIG. 12 is a schematic diagram explaining a response when data is affected by the frequency shift.

Throughout the figures, the same reference numerals, and characters, unless otherwise noted, are used to denote like features, elements, components, or portions of the illustrated embodiment.

### DETAILED DESCRIPTION OF THE PREFERRED EMBODIMENTS

The preferred embodiments of the present invention will be described in detail, referring to the accompanying drawings.

### First Embodiment

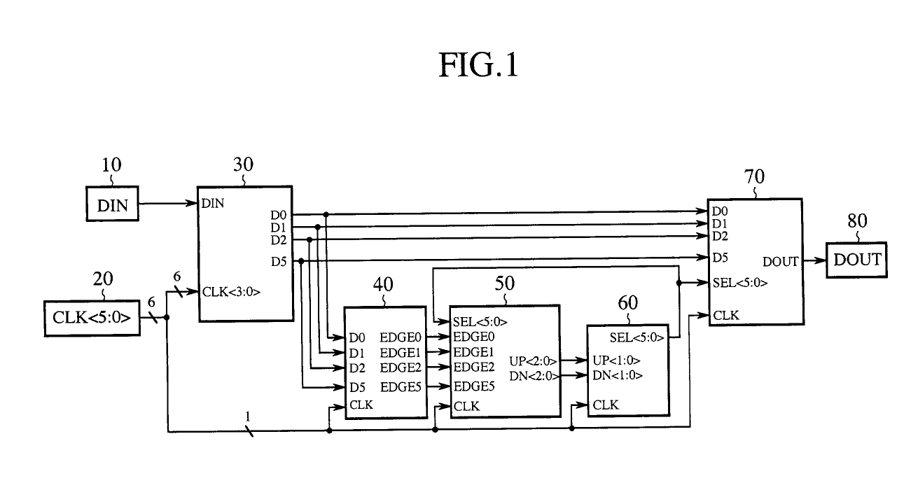

FIG. 1 is a block diagram showing an exemplary configuration of a clock extraction circuit according to the first embodiment.

Referring to FIG. 1, reference numeral 10 denotes a data input terminal for inputting data, 20 denotes a clock input terminal for inputting a 6-phase clock, 30 denotes a sampling unit for latching input data using the 6-phase clock and for retiming at a specific phase out of the 6-phase clock, 40 denotes an edge detection unit for detecting a phase at which a leading edge or a trailing edge is coincided out of an output data and for outputting the detected results, 50 denotes a phase judgement unit for relatively comparing a phase at which a leading edge or a trailing edge is coincided and a position of the currently selected data, and for outputting a signal for increasing or decreasing a count value of the counter 60 at the subsequent stage depending on the results, 60 denotes a counter that has a threshold therein and when the count value exceeds the threshold, it moves forward and backward a data selecting position SEL, 70 denotes a data selector for outputting a data that comes under an output data SEL of the counter 60 to the subsequent stage out of output data D0 to D5 of the sampling unit 60.

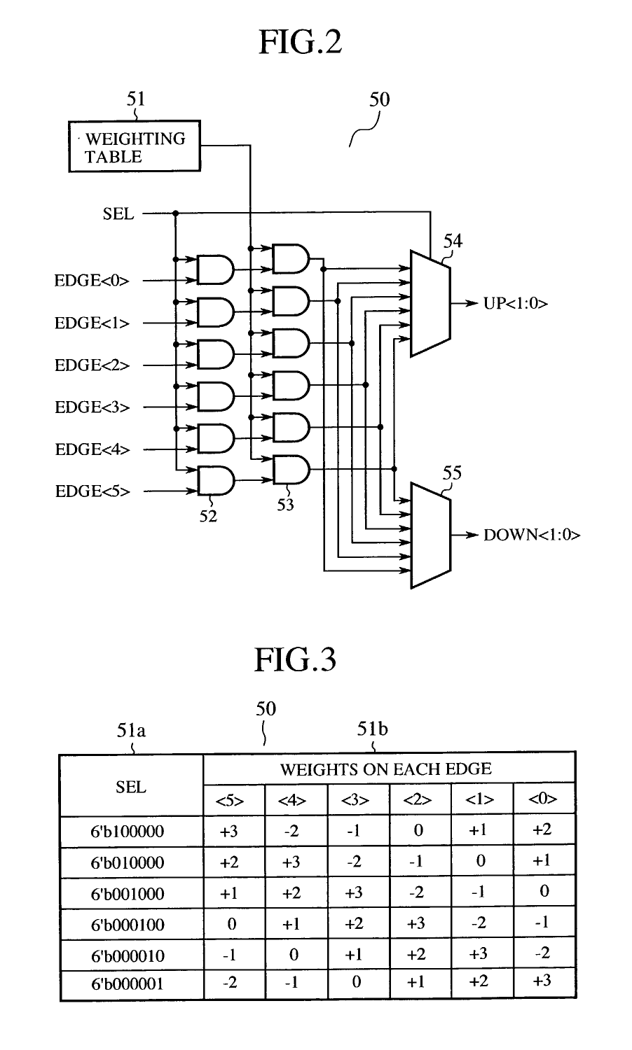

FIG. 2 is a block diagram showing an exemplary internal configuration of the phase judgement unit 50.

Referring to FIG. 2, reference numeral 51 denotes a weighting table in which weights are set in order to put a weight on detected results of the edge detection unit 40, 52, 53 denote AND circuits, 54, 55 denote logical gates for generating UP and DOWN signals from a SEL (data selection) signal, an EDGE (edge position) signal, and AND of the weighting table 51.

FIG. 3 is a table showing an exemplary contents of the weighting table 51.

Referring to FIG. 3, reference numeral 51a denotes each SEL signal, 51b denotes weights on each EDGE signal. As shown in FIG. 3, the weighting is varied depending on which of SEL signal selects. When a leading edge is directly opposed to a trailing edge, a weight is set to “0”. Thus, the weighting increases as the SEL signal and the leading edge or the trailing edge are closed each other.

The operation of the clock extraction circuit of the first embodiment will now be described.

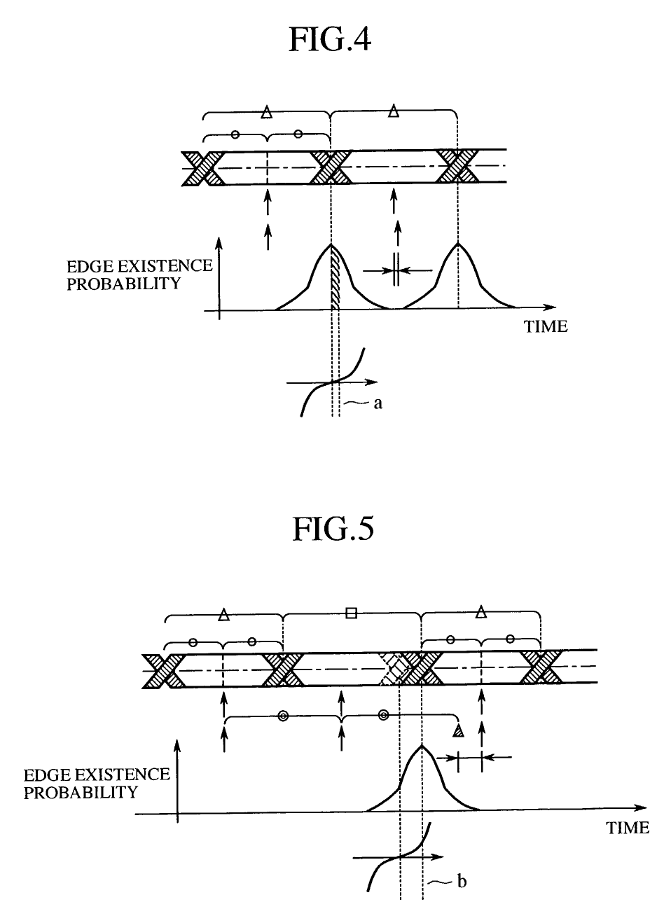

FIG. 4 is a schematic diagram explaining a response and weighting when data is affected by the random jitter. FIG. 5 is schematic diagram explaining a response and weighting when data is affected by the frequency shift.

In the case where data is affected by the random jitter, as shown in FIG. 4, an edge existence probability will become large in the vicinity of the jitters due to the nature of the Gaussian distribution. In this event, a SEL signal, e.g., “SEL=6′b000010” is selected from the weighting table to put a small weight on the region as indicated by reference character a. Thus, since an absolute value of the count increase and decrease in the counter 60 and consequently a shifting amount of a clock becomes small, the clock extraction circuit is hardly affected by the random jitter, thereby allowing an appropriate response.

On the contrary, in the case where data is affected by the frequency shift, as shown in FIG. 5, the center of the jitter drifts forward and backward. In this event, a SEL signal, e.g., “SEL=6′b0000001” is selected from the weighting table to put a large weight on the region as indicated by reference character b. Hence, since an absolute value of the count increase and decrease in the counter 60 becomes large and consequently a shifting amount of a clock becomes small, the clock extraction circuit can appropriately response to the input data that is subjected to the frequency shift.

As is clear from the above description, according to the first embodiment, since the contents of the weighting table is set such that a small weight is put on the random jitter having the Gaussian distribution, while a large weight is put on the frequency shift, it can manage both random jitter and frequency shift.

### Second Embodiment

In this second embodiment, only the contents of the weighting table 51 in the phase judgement unit 50 is different from that of the first embodiment, and therefore descriptions of the same components as the first embodiment are omitted for brevity's sake. Besides, an illustration of a table showing an exemplary contents of the weighting table 51 of the second embodiment is also omitted for the same reason.

In the second embodiment, the contents of the weighting table 51 is set to “0” for the random jitter, while to “1” for the frequency shift.

The operation of the clock extraction circuit of the second embodiment will now be described.

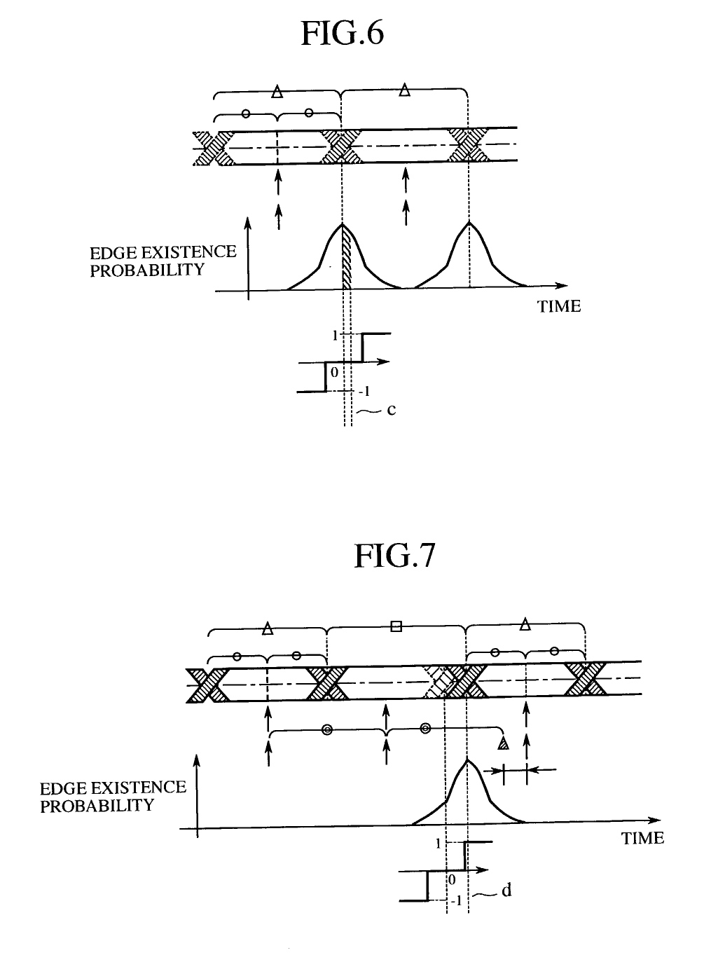

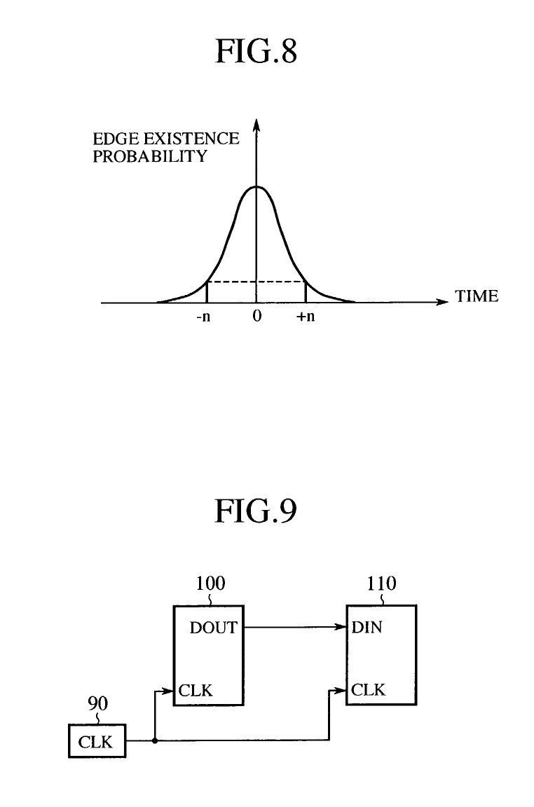

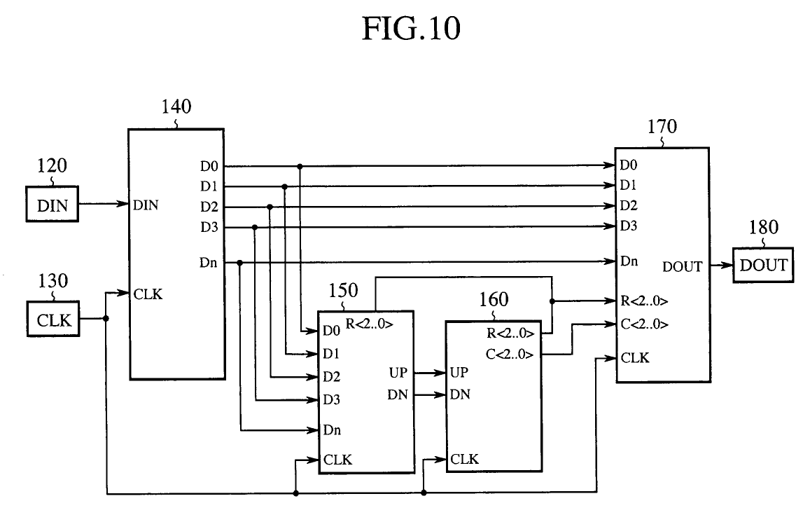

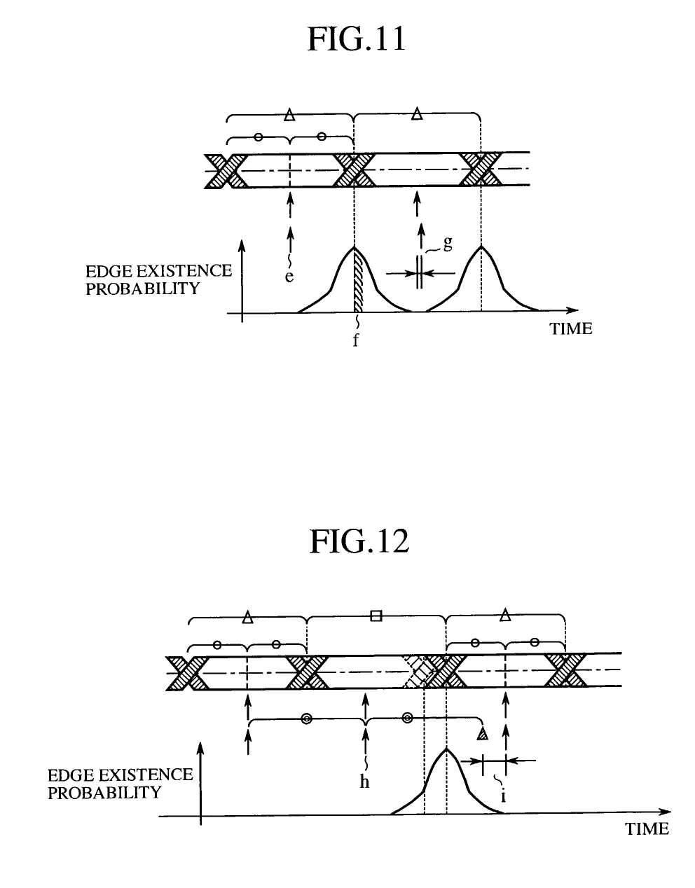

FIG. 6 is a schematic diagram showing a response and measures thereof when data is affected by the random jitter. FIG. 7 is a schematic diagram showing a response and measures thereof when data is affected by the frequency shift.

In the case where data is affected by the random jitter, as shown in FIG. 6, it has a large edge existence probability in the vicinity of the center of jitters due to the nature of a Gaussian distribution, a weight of “0” is put on the region (within a predetermined region) as indicated by reference character c. Thus, a count increase and decrease of the counter 60 come to 0 and consequently a clock does not shift. Accordingly, the clock extraction circuit is hardly affected by the random jitter, thereby allowing an appropriate response.

On the contrary, in the case where data is affected by the frequency shift, as shown in FIG. 7, since the center of jitter drifts forward and backward, a weight of “1” is put on the region (without a predetermined region) as indicated by reference character d. Hence, a count increase and decrease of the counter 60 do not undergo a change and a shifting amount of a clock remains unchanged. Accordingly, the clock extraction circuit can appropriately response to the input data that is subjected to the frequency shift.

As is clear from the above description, according to the second embodiment, since a weight of “0” is put on the random jitter having the Gaussian distribution, while a weight of “1” is put on the frequency shift, it is not only hardly affected by the random jitter but quickly responses to the frequency shift. This can reduce circuit scale and power consumption as well as manage both the random jitter and the frequency shift.

While in the first and second embodiments an output of the sampling unit 30 using a 6-phase clock for explanation is selected by the data selector 70, it is appreciated that an output of the delay unit 140 may be selected by the data selector 70 like the Related Art.

Further, while weights of the weighting table 51 are set as shown in FIG. 3, as a result of the 6-phase clock, as a mater of course, more or less phase clock may be adopted.

Moreover, while a description has been made on assumption that weights are previously set into the weighting table 51, without being limited thereto, e.g., a circuit may be separately provided for detecting the random jitter and the frequency shift in order to dynamically set corresponding weights depending the random jitter or the frequency shift.

While, in the above prior arts and preferred embodiments of the invention, it should be understood by those skilled in the art that various modifications and changes may be made without departing from the sprit and scope of the invention.

Also, it should be noted that the invention meets all the objects mentioned above and also has the advantages of wide commercial utility, and that the invention has been set forth for purposes of illustration only and not of limitation. That is, the invention is limited only by the following claims which follow. Consequently, reference should be made to the following claims in determining the full scope of the invention.

What is claimed is:

1. A clock extraction circuit for extracting a clock in accordance with input data on high speed data transmission, comprising:
an edge detection unit for detecting a phase at which a trailing edge or a leading edge of the input data is coincided with each other;
a phase judgement unit for comparing an edge position of the detected input data and a position of input clock, and for putting a weight;
wherein said weight is put so that a shifting amount of the clock is changed in accordance with a difference between the edge position of the input data and the position of the input clock.

2. The clock extraction circuit according to claim 1, wherein said phase judgement unit comprises an weighting table in which weights are set to put a weight in accordance with a difference between the edge position of the input data and the position of the input clock.

3. The clock extraction circuit according to claim 1, wherein a small weight is put so that the shifting amount of the input clock becomes small in the case where a difference between the edge position of the input data and the position of the clock is small, a large weight being put so that the shifting amount of the input clock becomes large in the case where a difference between the edge position of the input data and the position of the input clock is large.

4. A clock extraction circuit for extracting a clock in accordance with input data on high speed data transmission, comprising:
an edge detection unit for detecting a phase at which a trailing edge or a leading edge of the input data is coincided with each other;
a phase judgement unit for comparing an edge position of the detected input data and a position of an input clock, and for putting a weight;
wherein said weight is varied depending on whether or not a difference between an edge position of the input data and the position of the input clock falls within a predetermined region.

5. The clock extraction circuit according to claim 4, wherein said judgement unit comprises an weighting table in which weights are set to put a weight in accordance with whether or not a difference between the edge position of the input data and the position of the input clock falls within a predetermined region.

6. The clock extraction circuit according to claim 4, wherein a small weight is put in the case where a difference between the edge position of the input data and the position of the input clock falls within a predetermined region, a large weight being put in the case where a difference between the edge position of the input data and the position of the input clock does not fall within a predetermined region, so as not to shift the input clock.
